(19) United States
(12) Patent Application Publication
(10) Pub. No.: US 2011/0148288 A1
(43) Pub. Date: Jun. 23, 2011

(54) Organic Light-Emitting Device, Pixel Structure, and Contact Structure, and Method for Fabricating the Same

(75) Inventors: Chieh Wei Chen, Hsin-Chu (TW); Chun Hsiang Fang, Hsin-Chu (TW)

(73) Assignee: AU OPTRONICS CORPORATION, Hsin-Chu (TW)

(21) Appl. No.: 12/820,645

(22) Filed: Jun. 22, 2010

(30) Foreign Application Priority Data
Dec. 17, 2009 (TW) 098143305

(51) Int. Cl. H01J 1/63; H01J 9/02

(52) U.S. Cl. 313/504; 445/35

(57) ABSTRACT

A contact structure for organic luminescent devices is provided. The contact structure includes a first conductive layer, at least one pillar, an organic light-emitting layer, and a second conductive layer. The first conductive layer has a contact region. The at least one pillar is positioned on the first conductive layer in the contact region. The organic light-emitting layer covers the first conductive layer in the contact region and exposing a portion of the first conductive layer around the pillar in the contact region. The second conductive layer covers an exposed portion of the first conductive layer in the contact region. In one embodiment of the present invention, the pillar has a top surface and a bottom surface, and the width of the top surface is larger than that of the bottom surface.

### TECHNICAL FIELD

The present invention relates to an organic light-emitting device and method for preparing the same, and more particularly, to an organic light-emitting device having series-connected luminescent devices and method for preparing the same.

### BACKGROUND

Organic light-emitting diode (OLED) displays such as the organic electroluminescent displays have advantages of small size, high resolution, high contrast ratio, low power consumption, and active luminescence, which put the organic electroluminescent displays in position to surpass the is conventional liquid crystal displays as the prevailing technology for the next generation of flat panel display design.

FIG. 1 is a schematic diagram illustrating a driving circuit structure of a conventional organic light-emitting device 1. As shown in FIG. 1, the organic light-emitting device 1 includes two thin film transistors T1, T2, one capacitor C, and one luminescent device. The gate electrode of the thin film transistor T1 is connected to a scan line, and a source electrode and a drain electrode are respectively connected to a data line and a gate electrode of the thin film transistor T2. A source electrode of the thin film transistor T2 is connected to a voltage source Vdd, and a drain electrode of the thin film transistor T2 is connected to an anode of the luminescent device. The cathode of the luminescent device is connected to a voltage source Vss.

To enlarge the display area of the organic light-emitting device, the area of the luminescent device between the thin film transistors T1 and the voltage source Vss is increased. The increase in the area of the luminescent device is equivalent to connecting several small luminescent devices in parallel. However, if a short circuit occurs between the anode and cathode of one of the small luminescent devices, all current will flow through the formed short circuit, and all of the luminescent device will fail to emit light. To resolve this, researchers attempt to connect several small luminescent devices in series between the thin film transistors T2 and the voltage source Vss. However, implementing this series-connected circuit structure needs a connecting technique to connect the cathode of a luminescent device to the anode of an adjacent luminescent device. In addition, connecting several luminescent devices in series between the thin film transistors T2 and the voltage source Vss causes the light-emitting intensity to vary with variations in the current.

### SUMMARY

In one aspect of the present invention, a short circuit occurs between is the anode and cathode of one of the small luminescent devices is prevented.

The present invention provides a contact structure for organic luminescent devices with at least one pillar formed on anode of the luminescent device in the contact region severed as a mask to connect the cathode of an adjacent luminescent device to the anode of the luminescent device without additional photolithography process and the cost of manufacture can be reduced.

One aspect of the present invention provides an organic light-emitting device having a plurality of luminescent devices connected in series. In one embodiment of the present invention, the organic light-emitting device comprises a substrate and a plurality of adjacent luminescent devices, each luminescent device comprising a first electrode positioned on the substrate and having a light-emitting region and a contact region; a passivation layer covering a portion of the first electrode and exposing the light-emitting region and the contact region of the first electrode; a partition wall positioned on the passivation layer and separating the light-emitting region and the contact region; at least one pillar positioned on the first electrode in the contact region, the pillar having a top surface and a bottom surface, and the width of the top surface being larger than that of the bottom surface; an organic light-emitting layer covering a portion of the first electrode in the light-emitting region and covering a portion of the first electrode in the contact region of an adjacent luminescent device, and exposing a portion of the first electrode around the pillar in the contact region of the adjacent luminescent device; and a second electrode covering the organic light-emitting layer in the light-emitting region and covering a portion of an uncovered first electrode in the contact region of the adjacent luminescent device.

Another aspect of the present invention provides an organic light-emitting pixel structure having a plurality of luminescent devices connected in series. In one embodiment of the present invention, the organic light-emitting pixel structure is formed on a substrate having a switching region and a device region adjacent to the switching region. In one embodiment of the present invention, the organic light-emitting pixel structure comprises a first electrode positioned on the substrate in the device region, the first electrode having a light-emitting region and a contact region; a passivation layer covering a portion of the first electrode and exposing the light-emitting region and the contact region of the first electrode; a partition wall positioned on the passivation layer and surrounding the light-emitting region; at least one pillar positioned on the first electrode in the contact region, the pillar having a top surface and a bottom surface, and the width of the top surface being larger than that of the bottom surface; an organic light-emitting layer covering the first electrode in the light-emitting region, covering a portion of the first electrode in the contact region of an adjacent luminescent device, and exposing a portion of the first electrode around the pillar in the contact region of the adjacent luminescent device; and a second electrode covering the organic light-emitting layer and covering a portion of an uncovered first electrode in the contact region of the adjacent luminescent device.

Another aspect of the present invention provides a contact structure for organic luminescent devices comprising a first conductive layer having a contact region; at least one pillar positioned on the first conductive layer in the contact region, the pillar having a top surface and a bottom surface, and the width of the top surface being larger than that of the bottom surface; an organic light-emitting layer covering the first conductive layer in the contact region and exposing a portion of the first conductive layer around the pillar in the contact region; and a second conductive layer covering a portion of an uncovered first conductive layer in the contact region.

Another aspect of the present invention provides a method for preparing an organic light-emitting device comprising forming a first electrode on a substrate, the first electrode having a light-emitting region and a contact region; forming a passivation layer on the first electrode, the passivation layer covering a portion of the first electrode and exposing the is light-emitting region and the contact region of the first electrode; forming a partition wall and at least one pillar, the partition wall being formed on the passivation layer and separating the light-emitting region and the contact region, the pillar being formed on the first electrode in the contact region and having a top surface and a bottom surface, and the width of the top surface being larger than that of the bottom surface; forming an organic light-emitting layer by vapor deposition, the organic light-emitting layer covering a portion of the first electrode in the light-emitting region and covering a portion of the first electrode in the contact region of an adjacent luminescent device, and exposing a portion of the first electrode around the pillar in the contact region of the adjacent luminescent device; and forming a second electrode by vapor deposition, the second electrode covering the organic light-emitting layer in the light-emitting region and covering a portion of an uncovered first electrode in the contact region of the adjacent luminescent device.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed might be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the invention and, together with the description, serve to explain the principles of the invention.

is FIG. 1 is a schematic diagram illustrating a driving circuit structure of a conventional organic light-emitting device;

FIGS. 2 to 14 illustrate a method for preparing an organic light-emitting device according to one embodiment of the present invention;

FIG. 15 illustrates a circuit diagram of an organic light-emitting pixel structure according to one embodiment of the present invention; and

FIGS. 16 to 26 illustrate the fabrication method of the organic light-emitting pixel structure according to one embodiment of the present invention.

### DETAILED DESCRIPTION

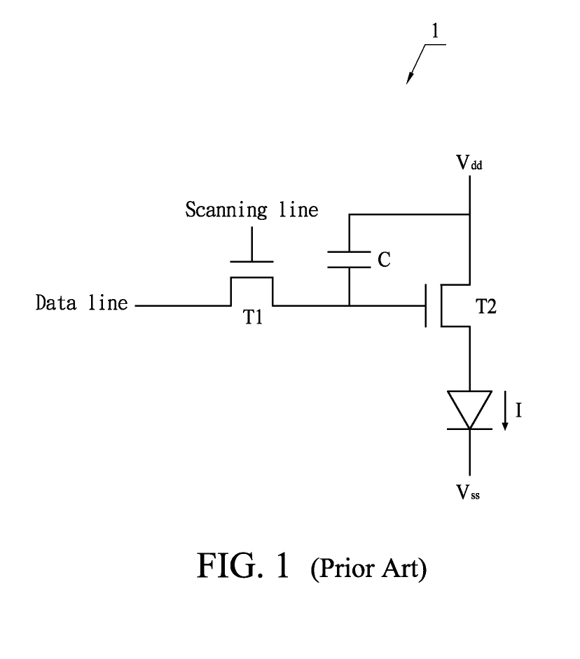

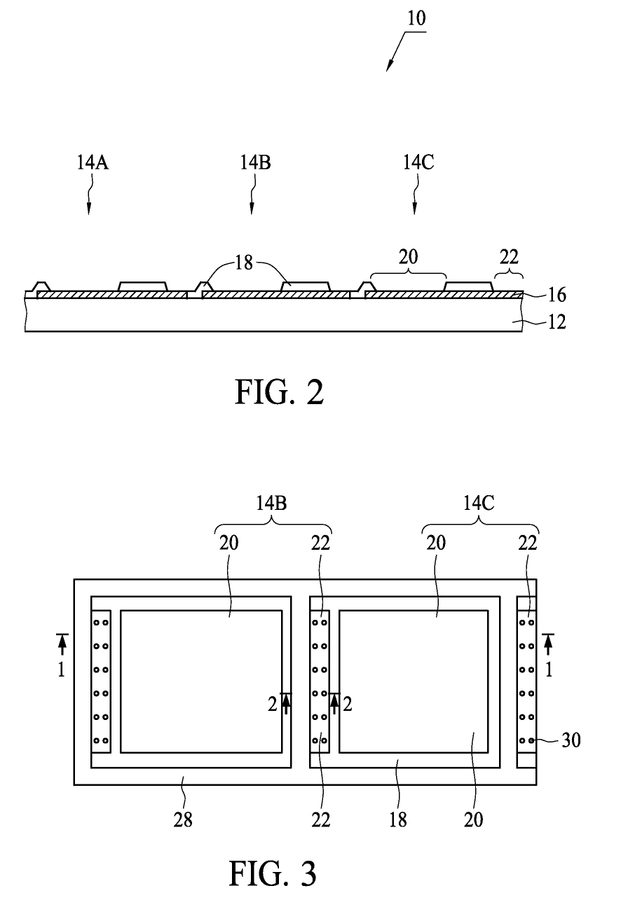

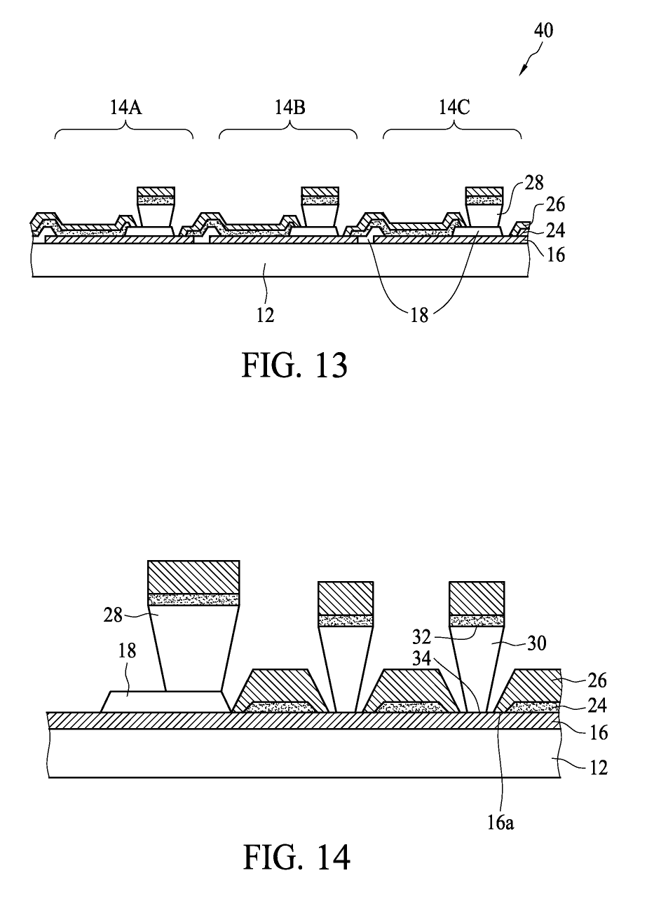

FIGS. 2 to 14 illustrate a method for preparing an organic light-emitting device 10 according to one embodiment of the present invention. First, a first electrode 16 such as the anodes of a plurality of luminescent devices 14A to 14C is formed on a substrate 12 and a passivation layer 18 is then formed on the substrate 12, wherein the first electrode 16 has a light-emitting region 20 and a contact region 22, and the passivation layer 18 covers a portion of the first electrode 16 and exposes the light-emitting region 20 and the contact region 22 of the first electrode 16. In a bottom-emission type organic electroluminescent display panel, the material of the anodes 16 can be a transparent conductive material such as indium-tin oxide (ITO), indium-zinc oxide (IZO), aluminum-zinc oxide (AZO), or combinations thereof; in contrast, in a top-emission type organic electroluminescent display panel, the material of the anodes 16 in this situation may be metal, such as aluminum, copper, silver, gold, titanium, tungsten or combinations thereof.

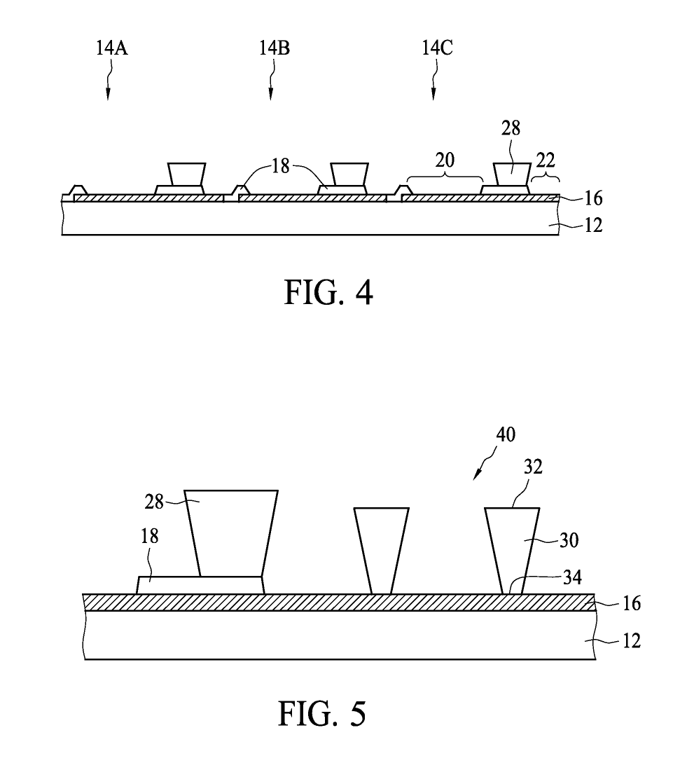

FIG. 3 illustrates a top view showing a portion of the organic light-emitting device 10 according to one embodiment of the present invention. FIG. 4 is a sectional view along line 1-1 in FIG. 3. FIG. 5 is a sectional is view along line 2-2 in FIG. 3. Referring to FIG. 3, a lithographic process is performed to form a partition wall 28 and a shielding structure 40 including at least one pillar 30 formed on the first electrode 16 in the contact region 22 together. In an alternative embodiment, the partition wall 28 and the at least one pillar 30 can be separately formed in two lithographic processes. Referring to FIG. 5, the pillar 30 has a top surface 32 with a top width and a bottom surface 34 with a bottom width, and the top width of the top surface 32 is larger than the bottom width of the bottom surface 34. In a vertical sectional view of the pillar 30, the included angle between the sidewall of the pillar 30 and the surface of the substrate 12 is smaller than 90 degrees. For example, the vertical sectional view of the pillar 30 is a reversed trapezoid shape, and the width of the reversed trapezoid shape is larger at an upper end than that at the bottom end.

Referring back to FIG. 3, the partition wall 28 surrounds the light-emitting region of one luminescent device and the contact region of another adjacent luminescent device. For example, the partition wall 28 surrounds the light-emitting region 20 of one luminescent device 14C and the contact region 22 of another adjacent luminescent device 14B. In one embodiment of the present invention, the partition wall 28 and the shield structure 40 can be formed in the same lithographic process, or by separate lithographic processes. In one embodiment of the present invention, the pillar 30 may include a circular base 30A and a reversed trapezoid top 30B.

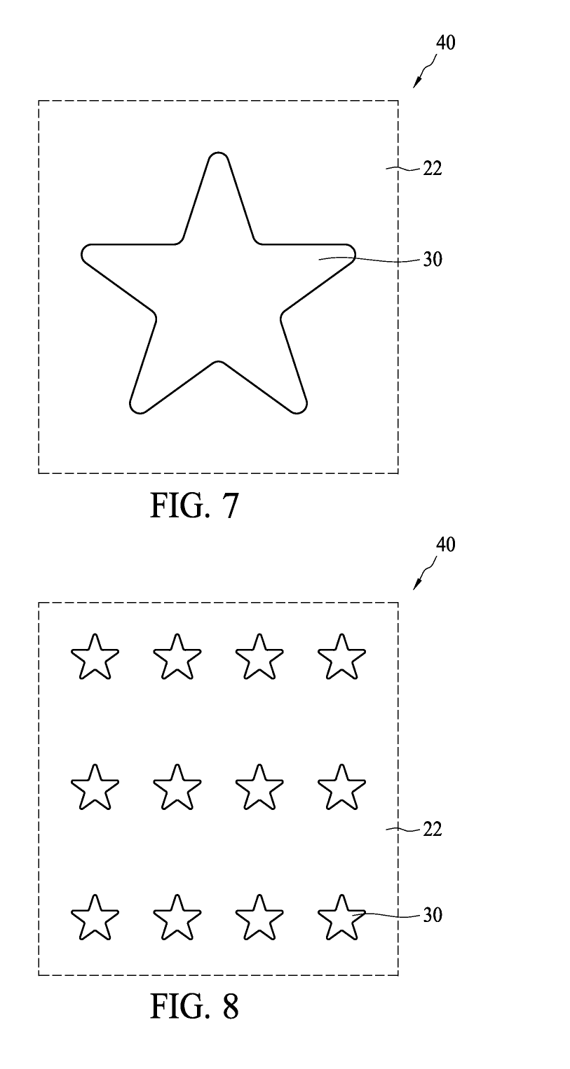

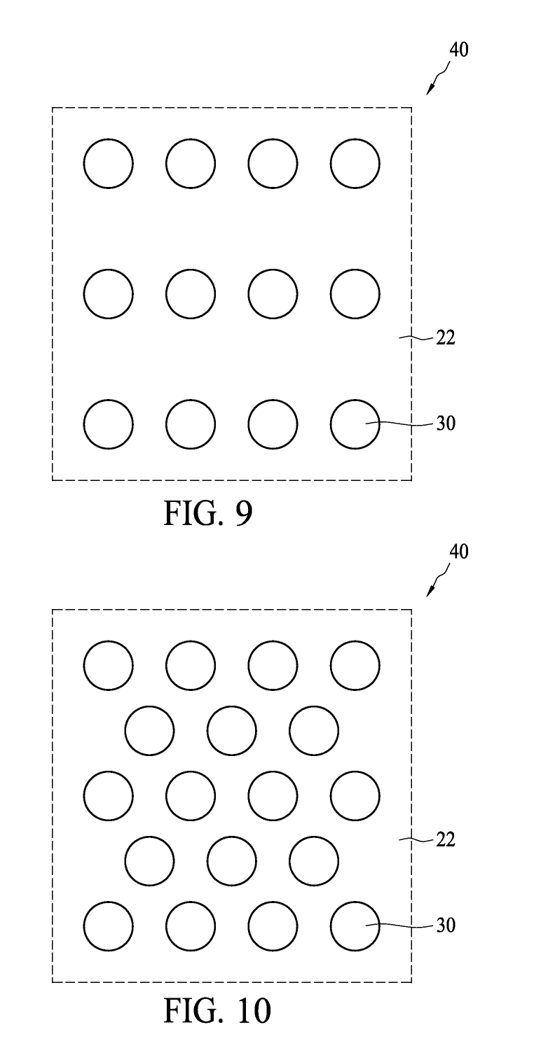

FIGS. 7 to 10 illustrate several embodiments of the shielding structure 40. In one embodiment of the present invention, the horizontal sectional view of the pillar 30 of the shielding structure 40 is a star, as shown in FIG. 7. In one embodiment of the present invention, the shielding structure 40 includes a plurality of pillars 30 positioned in an array matrix (mxn) in the contact region 22, where m and n are positive integers, as shown in FIG. 8 and FIG. 9. In one embodiment of the present invention, the shielding structure 40 includes a plurality of pillars 30 positioned in a plurality of odd rows and a plurality of even rows in the contact region 22, and each of the pillars 30 in the even rows is positioned at an interval between an adjacent pair of pillars 30 in the odd rows, as shown in FIG. 8 and FIG. 9. In one embodiment of the present invention, the shielding structure 40 includes a plurality of pillars 30, and the horizontal sectional view of the pillars 30 is a star or circle, as shown in FIG. 8 and FIG. 9.

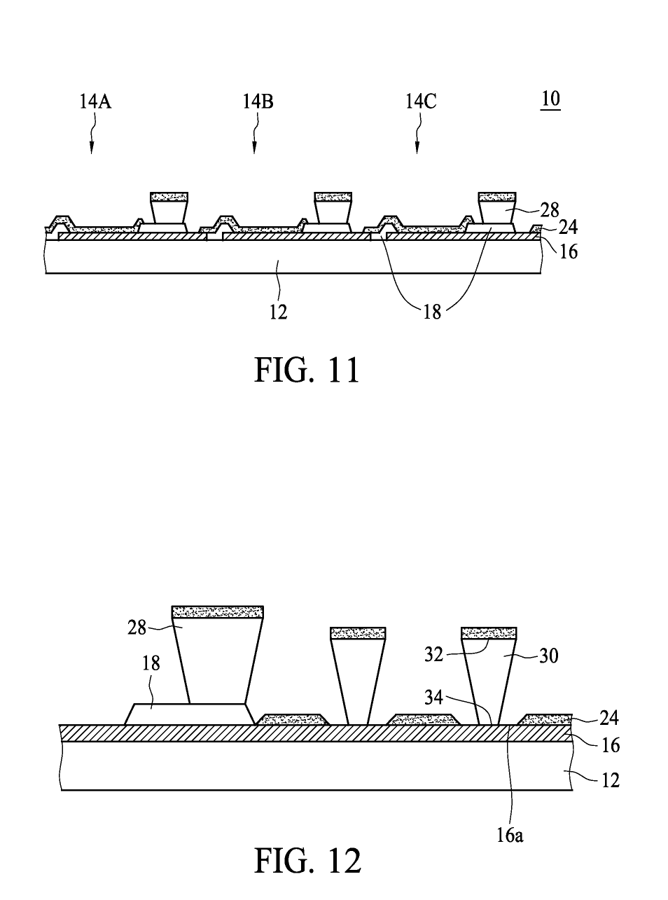

FIG. 12 is an enlargement view showing a portion of the contact region 22. In FIGS. 11 and 12, a vapor deposition process is performed to form an organic light-emitting layer 24 on the first electrode 16. By using the shielding effect of the pillars 30 of the shielding structure 40, the vapor deposition process can form the organic light-emitting layer 24 without using an additional metal shielding plate such that the organic light-emitting layer 24 only covers a portion of the first electrode 16 in the light-emitting region 20 as shown in FIG. 11, and covers a portion of the first electrode 16 in the contact region 22 of an adjacent luminescent device and exposes an exposed portion 16a of the first electrode 16 around the pillar 30 in the contact region 22 of the adjacent luminescent device, as shown in FIG. 12.

FIG. 14 is a close-up view showing a portion of the contact region 22. In FIGS. 11 and 12, a vapor deposition process is performed to form a second electrode such as the anode 26. The second electrode 26 covers the organic light-emitting layer 24 in the light-emitting region 20 and covering the exposed region 16a of the uncovered first electrode 16 in the contact region 22 of the adjacent luminescent device. By using the shielding effect of the pillars 30 of the shielding structure 40, the organic light-emitting layer 24 does not completely cover the first electrode 16 in the contact region 22 of the luminescent device 14B, and the subsequently formed second electrode 26 of the luminescent device 16C can contact the first electrode 16 in the contact region 22 of the adjacent luminescent device 14B, i.e., implementing the series connection of the second electrode 26 of the luminescent device 16C to the first electrode 16 in the contact region 22 of the adjacent luminescent device 14B. Similarly, the second electrode 26 of the luminescent device 16B is connected in series to the first electrode 16 is in the contact region 22 of the adjacent luminescent device 14A. In other words, the luminescent devices 14A to 14C are connected in series.

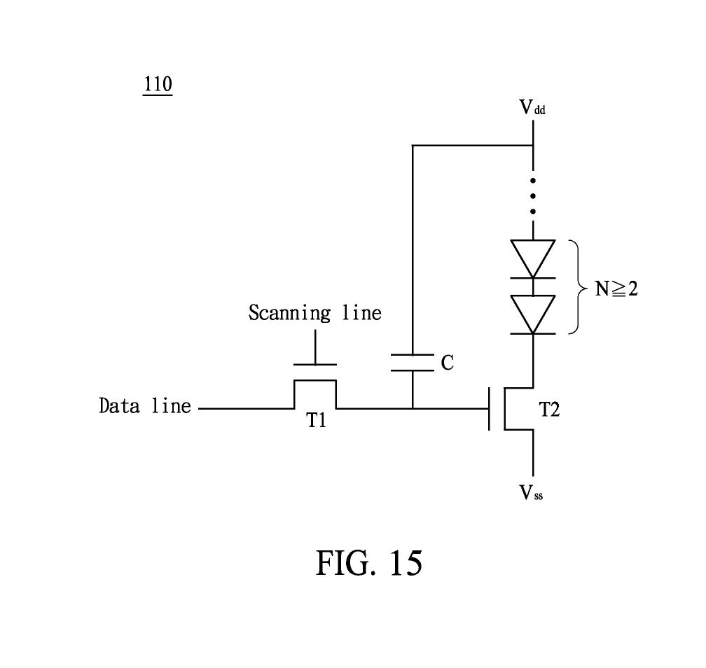

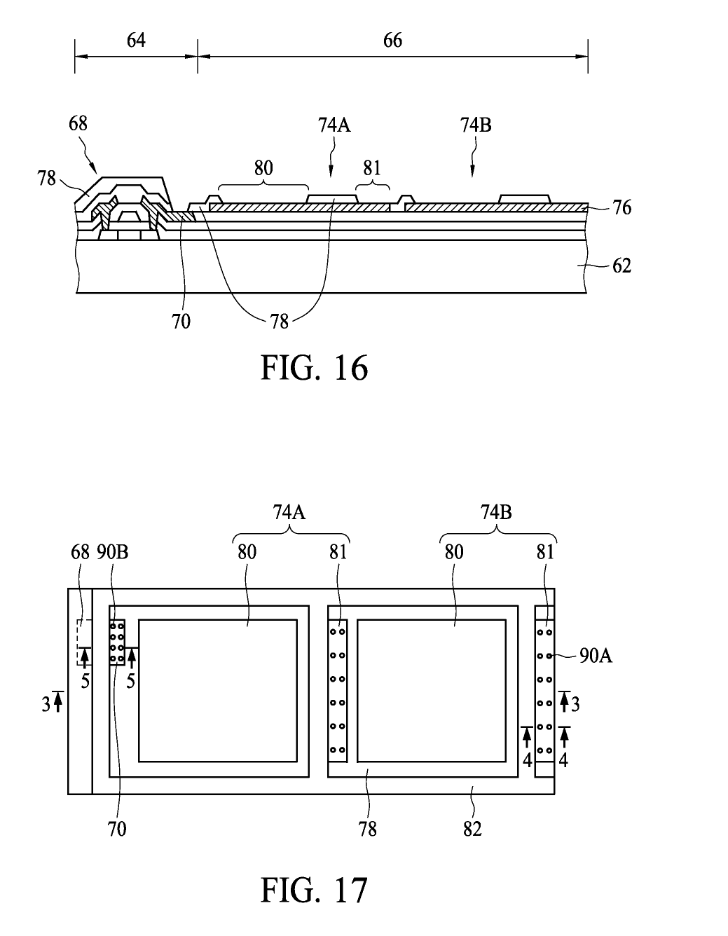

FIG. 15 illustrates a circuit diagram of an organic light-emitting pixel structure 110 according to one embodiment of the present invention, and FIGS. 16 to 26 illustrate the fabrication method of the organic light-emitting pixel structure 110 according to one embodiment of the present invention. The organic light-emitting pixel structure 110 comprises two thin film transistors T1, T2, one capacitor C, and a plurality of series-connected luminescent devices. The gate electrode of the thin film transistor T1 is connected to a scan line, and a source electrode and a drain electrode are respectively connected to a data line and a gate electrode of the thin film transistor T2. In one embodiment, a source electrode of the thin film transistor T2 can be connected to an anode of the series-connected luminescent devices, and a drain electrode of the thin film transistor T2 can be connected to a voltage source Vss. The series-connected luminescent device is positioned between the source electrode of the thin film transistor T2 and a voltage source Vdd to reduce the effect of the increased voltage across the luminescent device on the thin film transistor T2. In an alternative embodiment, the drain electrode of the thin film transistor T2 can be connected to an anode of the series-connected luminescent devices, and the source electrode of the thin film transistor T2 can be connected to a voltage source Vss. The source electrode and the drain electrode of the thin film transistor T2 can be named into two source/drain electrodes. One source/drain electrode is the source electrode and the other source/drain electrode is the drain electrode. This is well known to a person skilled in the art, and not described in detail herein.

Referring to FIG. 16, the organic light-emitting pixel structure 110 is formed on a substrate 62 having a switching region 64 and a device region 66 adjacent to the switching region 64. The switching region 64 includes a thin film transistor 68, the device region 66 includes a plurality of luminescent device 74A and 74B having a first electrode 76 such as the anode, where the fabrication method of the thin film transistor is well is known in the art. A passivation layer 78 is formed on the first electrode 76 such that the passivation layer 78 covers a portion of the first electrode 76 and exposes a light-emitting region 80 and a contact region 81 of the first electrode 76. In addition, the passivation layer 78 also covers the thin film transistor 68 and exposes a source electrode 70 of the thin film transistor 68.

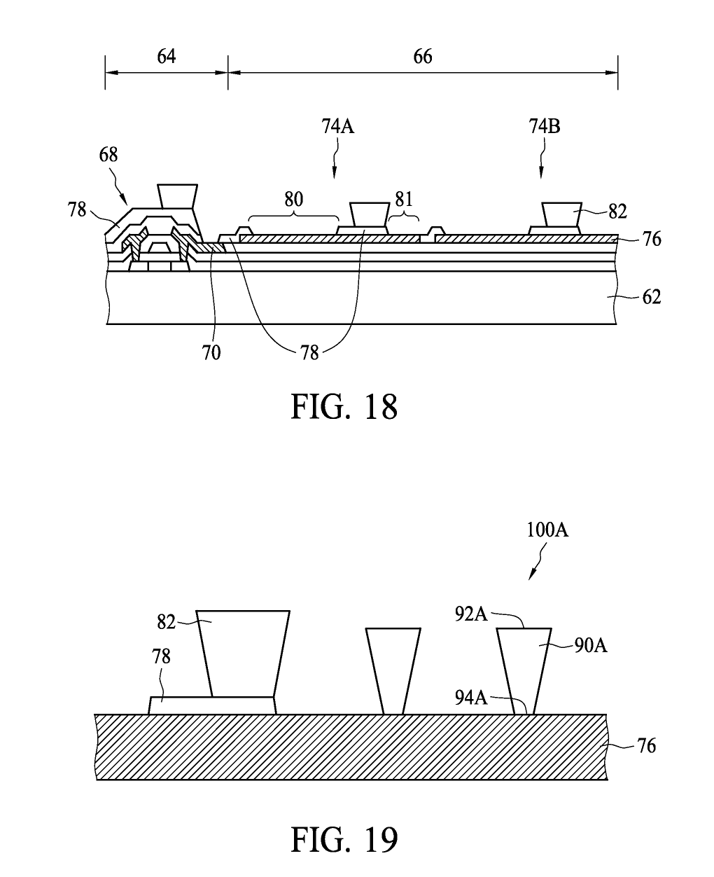

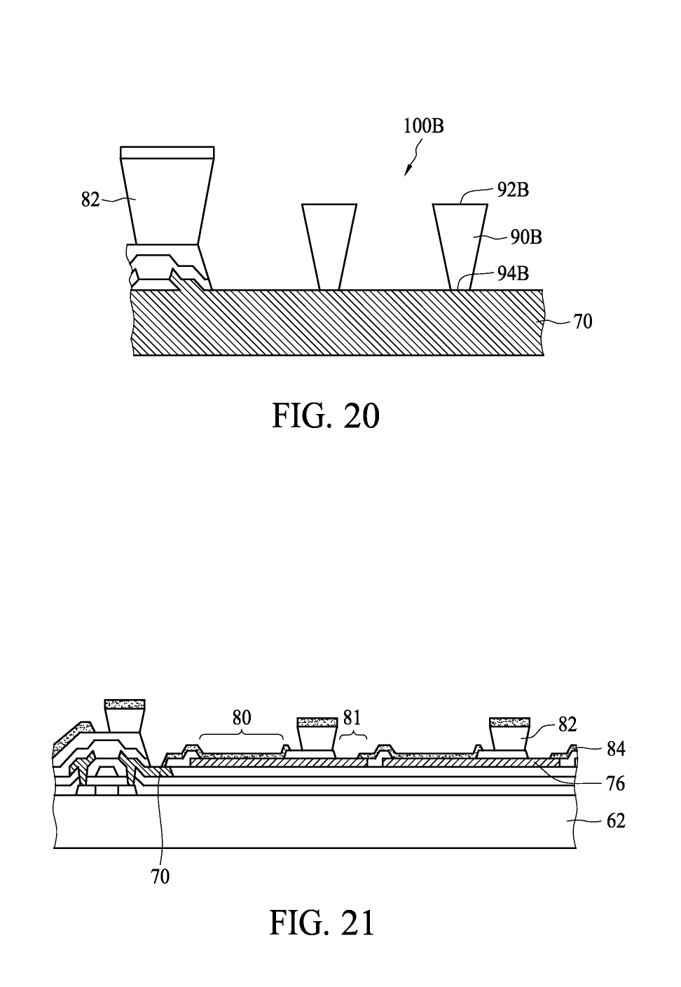

FIG. 17 illustrates a top view showing a portion of the organic light-emitting pixel structure 110 according to one embodiment of the present invention. FIG. 18 is a sectional view along line 3-3 in FIG. 17. FIG. 19 is a sectional view along line 4-4 in FIG. 17. FIG. 20 is a sectional view along line 5-5 in FIG. 17. Referring to FIG. 17, a lithographic process is performed to form a partition wall 82 on the passivation layer 78, a first shielding structure 100A and a second shielding structure 100B, as shown in FIG. 18. Referring to FIG. 16, the partition wall 82 separates the light-emitting region 80 from the contact region 81 of the luminescent device 74A, and separates the light-emitting region 80 from the contact region 81 of the luminescent device 74B. Referring to FIG. 19, the first shielding structure 100A includes at least one pillar 90A formed on the first electrode 76 in the contact region 81. Referring to FIG. 20, the second shielding structure 100B includes at least one pillar 90B formed on the source electrode 70 of the thin film transistor 68. In one embodiment of the present invention, the partition wall 88, the first shielding structure 100A, and the second shielding structure 100B can be formed in the same lithographic process, or by separate lithographic processes.

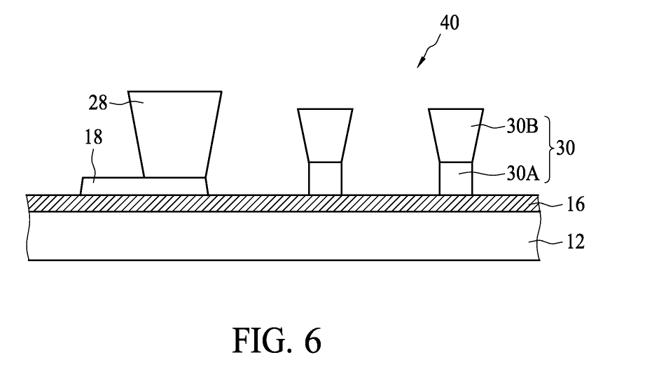

Referring to FIG. 19, the pillar 90A of the first shielding structure 100A has a top surface 92A and a bottom surface 94A, and the width of the top surface 92A is larger than that of the bottom surface 94A, i.e., the vertical sectional view of the pillar 90A is a reversed trapezoid, and the width of the reversed trapezoid is larger at an upper end than that at the bottom end. Referring to FIG. 20, the pillar 90B of the second shielding structure 100B has a top surface 92B and a bottom surface 94B, and the width of the top surface 92B is larger than that of the bottom surface 94B, is i.e., the vertical sectional view of the pillar 90B is a reversed trapezoid, and the width of the reversed trapezoid is larger at an upper end than that at the bottom end. In addition, the partition wall 82 surrounds the source electrode 70 of the thin film transistor 68 and the light-emitting region 80 of the luminescent device 74A, and the partition wall 82 also surrounds the contact region 81 of the luminescent device 74A and the light-emitting region 80 of the luminescent device 74B, as shown in FIG. 17. Furthermore, the first shielding structure 100A and the second shielding structure 100B can use the embodiment shown in FIGS. 6 to 10.

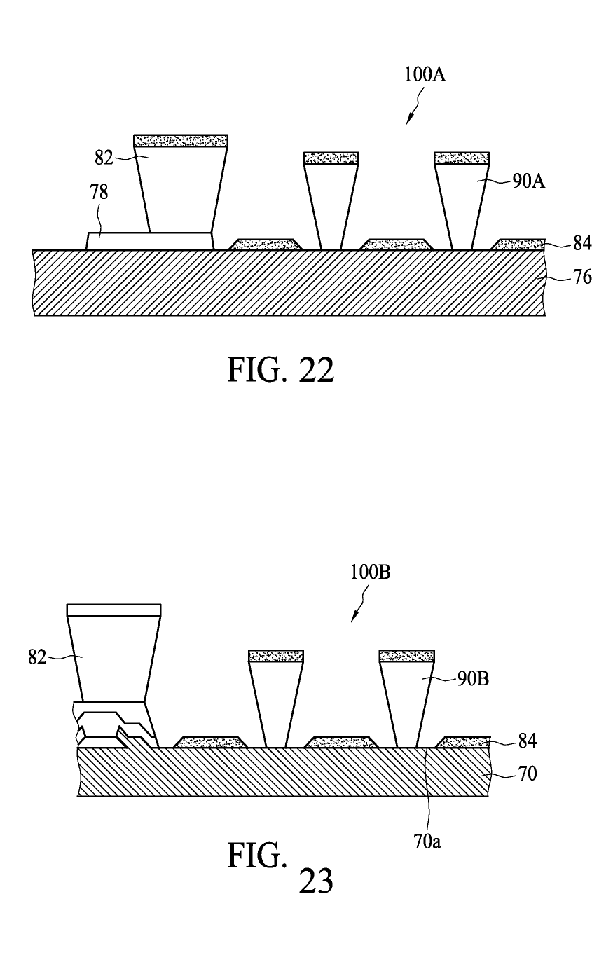

FIG. 22 is a close-up view showing a portion of the contact region 81. FIG. 23 is a close-up view showing a portion of the source electrode 70. In FIGS. 21 to 23, a vapor deposition process is performed to form an organic light-emitting layer 84 on the first electrode 76. Referring to FIG. 22, by using the shielding effect of the pillars 90A of the first shielding structure 100A, the vapor deposition process can form the organic light-emitting layer 84 without using an additional metal shielding plate severed as a shielding mask and the organic light-emitting layer 84 only covers a portion of the first electrode 76 in the light-emitting region 80, and covers a portion of the first electrode 76 in the contact region 81 of an adjacent luminescent device and exposes a portion of the first electrode 76 around the pillar 90A in the contact region 81 of the adjacent luminescent device. In addition, referring to FIG. 23, by using the shielding effect of the pillars 90B of the second shielding structure 100B, the vapor deposition process can form the organic light-emitting layer 84 without using an additional metal shielding plate and the automatically patterned organic light-emitting layer 84 only covers a portion of the source electrode 70 of the thin film transistor 68 and exposes an exposed portion 70a of the source electrode 70 around the pillar 90B.

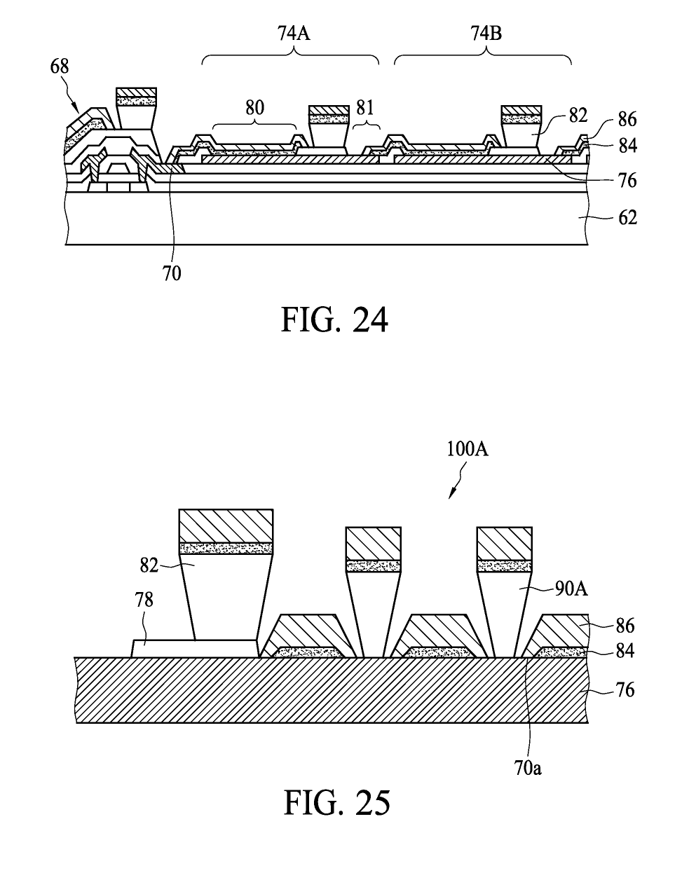

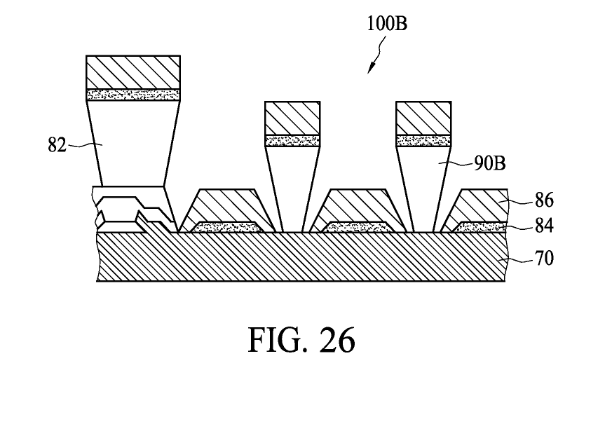

FIG. 25 is a close-up view showing a portion of the contact region 81. FIG. 26 is an enlargement view showing a portion of the source electrode 70. In FIGS. 24 to 26, a vapor deposition process is performed to form a is second electrode such as the anode 86. The second electrode 86 covers the organic light-emitting layer 84 in the light-emitting region 80 and covers a portion of an uncovered first electrode 76 in the contact region 81 of the adjacent luminescent device. By using the shielding effect of the shielding structure 100A, the organic light-emitting layer 84 does not completely cover the first electrode 76 in the contact region 81, and the subsequently formed second electrode 86 of the luminescent device 74B can contact the first electrode 76 in the contact region 81 of the adjacent luminescent device 74A, i.e., implementing the series connection of the second electrode 86 of the luminescent device 74B to the first electrode 76 in the contact region 81 of the adjacent luminescent device 74A. Similarly, by using the shielding effect of the shielding structure 100B, the organic light-emitting layer 84 does not completely cover the source electrode 70 of the thin film transistor 68, and the subsequently formed second electrode 86 of the luminescent device 74A can contact the exposed portion 70a of the source electrode 70 of the thin film transistor 68.

The present invention provide a contact structure for organic luminescent devices with at least one pillar formed on anode of the luminescent device in the contact region to severe as a mask. The organic light-emitting layer is automatically patterned and exposes an exposed portion around the pillar. The cathode of an adjacent luminescent device is automatically patterned and connected to the anode of the luminescent device. No additional photolithography process for the organic light-emitting layer and the cathode, and thus the cost of manufacture can be reduced.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the invention of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An organic light-emitting device, comprising:
a substrate; and
a plurality of luminescent devices adjacently arranged, each of the luminescent devices including:
a first electrode positioned on the substrate and having a light-emitting region and a contact region;
a passivation layer covering a portion of the first electrode and exposing the light-emitting region and the contact region of the first electrode;
a partition wall positioned on the passivation layer and separating the light-emitting region and the contact region;
at least one pillar positioned on the first electrode in the contact region, the pillar having a top surface with a top width and a is bottom surface with a bottom width, and the top width of the top surface being larger than the bottom width of the bottom surface;
an organic light-emitting layer covering a portion of the first electrode in the light-emitting region, the organic light-emitting layer covering a portion of the first electrode in the contact region and exposing an exposed portion of the first electrode around the pillar in the contact region of one luminescent device adjacent thereto; and
a second electrode covering the organic light-emitting layer in the light-emitting region, the second electrode covering the exposed portion of the first electrode in the contact region of the luminescent device adjacent thereto.

2. The organic light-emitting device of claim 1, wherein the second electrode of the luminescent device contacts a portion of the first electrode between the pillar and the organic light-emitting layer of the luminescent device adjacent thereto.

3. The organic light-emitting device of claim 1, wherein the pillar has a reversed trapezoid shape in vertical sectional view, and the width of the reversed trapezoid shape at the upper end is larger than that at the bottom end.

4. The organic light-emitting device of claim 1, wherein the pillar has a star shape at horizontal sectional view.

5. The organic light-emitting device of claim 1, wherein the at least one pillar comprises a plurality of pillars, and each of the pillars has a star shape or a circle shape at horizontal sectional view.

6. he organic light-emitting device of claim 1, wherein the at least one pillar comprises a plurality of pillars arranged in an array matrix in the contact region.

7. The organic light-emitting device of claim 1, wherein the at least one pillar comprises a plurality of pillars arranged in a plurality of odd is rows and a plurality of even rows, and each of the pillars in the even rows is positioned at an interval between an pair of pillars in the odd rows adjacent thereto.

8. The organic light-emitting device of claim 1, further comprising a thin film transistor electrically connected to the second electrode of the luminescent device.

9. An organic light-emitting pixel structure formed on a substrate having a device region, comprising:
a first electrode positioned on the substrate in the device region, the first electrode having a light-emitting region and a contact region;
a passivation layer covering a portion of the first electrode and exposing the light-emitting region and the contact region of the first electrode;
a partition wall positioned on the passivation layer and surrounding the light-emitting region;
at least one first pillar positioned on the first electrode in the contact region, the first pillar having a top surface with a top width and a bottom surface with a bottom width, and the top width of the top surface being larger than the bottom width of the bottom surface;
an organic light-emitting layer covering the first electrode in the light-emitting region, the organic light emitting layer covering a portion of the first electrode in the contact region, and exposing an exposed portion of the first electrode around the first pillar in the contact region; and
a second electrode covering the organic light-emitting layer in the light-emitting region and covering the exposed portion of the first electrode in the contact region.

10. The organic light-emitting pixel structure of claim 9, wherein the first pillar has a reversed trapezoid shape in vertical sectional view, and is the width of the reversed trapezoid shape at the upper end is larger than that at the bottom end.

11. The organic light-emitting pixel structure of claim 9, wherein the first pillar has a star shape at horizontal sectional view.

12. The organic light-emitting pixel structure of claim 9, wherein the at least one first pillar comprising a plurality of pillars, and each of the first pillars has a star shape or a circle shape at horizontal sectional view.

13. The organic light-emitting pixel structure of claim 9, wherein the at least one first pillar comprises a plurality of pillars arranged in an array matrix in the contact region.

14. The organic light-emitting pixel structure of claim 9, wherein the at least one first pillar comprises a plurality of pillars arranged in a plurality of odd rows and a plurality of even rows, and each of the pillars in the even rows is positioned at an interval between an pair of pillars in the odd rows adjacent thereto.

15. The organic light-emitting pixel structure of claim 9, further comprising a thin film transistor with a source electrode positioned in a switch region of the substrate adjacent to the device region and electrically connected to the second electrode by the source electrode.

16. The organic light-emitting pixel structure of claim 15, further comprising at least one second pillar positioned on the source electrode of the thin film transistor.

17. The organic light-emitting pixel structure of claim 16, wherein the organic light-emitting layer extends toward the switching region and covers a portion of the source electrode, and the second electrode extends toward the switching region and contacts the contact region between the at least one second pillar and the organic light-emitting layer.

18. A contact structure for organic luminescent devices, comprising:
a first conductive layer having a contact region;
at least one pillar positioned on the first conductive layer in the contact region, the pillar having a top surface with a top width and a bottom surface with a bottom width, and the top width of the top surface being larger than the bottom width of the bottom surface;
an organic light-emitting layer covering the first conductive layer in the contact region and exposing an exposed portion of the first conductive layer around the pillar in the contact region; and
a second conductive layer covering the exposed portion of first conductive layer in the contact region.

19. The contact structure for organic luminescent devices of claim 18, wherein the pillar has a reversed trapezoid shape in vertical sectional view, and the width of the reversed trapezoid shape at the upper end is larger than that at the bottom end.

20. The contact structure for organic luminescent devices of claim 18, wherein the first pillar has a star shape at horizontal sectional view.

21. The contact structure for organic luminescent devices of claim 18, wherein the at least one first pillar comprises a plurality of pillars arranged in an array matrix in the contact region.

22. The contact structure for organic luminescent devices of claim 18, wherein the at least one first pillar comprises a plurality of pillars arranged in a plurality of odd rows and a plurality of even rows, and each of the pillars in the even rows is positioned at an interval between an pair of pillars in the odd rows adjacent thereto.

23. The contact structure for organic luminescent devices of claim 18, wherein the at least one first pillar comprises a plurality of pillars, and each of the first pillars has a star shape or a circle shape at horizontal is sectional view.

24. An organic light-emitting pixel structure formed on a substrate having a device region and a switch region adjacent to the device region, comprising:
a thin film transistor having a source/drain electrode and positioned on the substrate in the switch region;
a first electrode positioned on the substrate in the device region;
a passivation layer covering the thin film transistor and exposing the first electrode and the source/drain electrode and;
a partition wall positioned on the passivation layer and surrounding the device region;
at least one pillar positioned on the source/drain electrode, the pillar having a top surface with a top width and a bottom surface with a bottom width, and the top width of the top surface being larger than the bottom width of the bottom surface;
an organic light-emitting layer covering the first electrode, the organic light emitting layer covering a portion of the source/drain electrode in the switch region, and exposing an exposed portion of the source/drain electrode around the pillar in the switch region; and
a second electrode covering the organic light-emitting layer in the device region and covering the exposed portion of the source/drain electrode in the switch region.

25. The organic light-emitting pixel structure of claim 24, wherein the source/drain electrode and the first electrode are formed in the same layer.

26. A method for preparing an organic light-emitting device, comprising:
forming a first electrode on a substrate, the first electrode having a light-emitting region and a contact region;
is forming a passivation layer on the first electrode, the passivation layer covering a portion of the first electrode and exposing the light-emitting region and the contact region of the first electrode;
forming a partition wall and at least one pillar, the partition wall being formed on the passivation layer and separating the light-emitting region and the contact region, the pillar being formed on the first electrode in the contact region and having a top surface with a top width and a bottom surface with a bottom width, and the top width of the top surface being larger than the bottom width of the bottom surface;
forming an organic light-emitting layer by a first vapor deposition process, the organic light-emitting layer covering a portion of the first electrode in the light-emitting region and covering a portion of the first electrode in the contact region, and exposing an exposed portion of the first electrode around the pillar in the contact region; and
forming a second electrode by a second vapor deposition process, the second electrode covering the organic light-emitting layer in the light-emitting region and covering the exposed portion of the first electrode in the contact region.

27. The method for preparing an organic light-emitting device of claim 26, wherein the step of forming of the partition wall and the at least one pillar comprise:
performing a first lithographic process to form the partition wall on the passivation layer; and
performing a second lithographic process to form the pillar on the first electrode in the contact region.

28. The method for preparing an organic light-emitting device of claim 26, wherein the step forming of the partition wall and the at least one pillar comprises performing a lithographic process to form the partition wall and the at least one pillar together.
